(19) United States
(12) Patent Application Publication
(10) Pub. No.: US 2009/0087583 A1
(43) Pub. Date: Apr. 2, 2009

(54) Film Deposition Method, Film Deposition Apparatus, and Storage Medium

(76) Inventors: Takashi Sakuma, Yamanashi-ken (JP); Osamu Yokoyama, Yamanashi-ken (JP); Taro Ikeda, Yamanashi-ken (JP); Tatsuo Hatano, Yamanashi-ken (JP); Yasushi Mizusawa, Albany, NY (US)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/226,610

(22) PCT Filed: Apr. 10, 2007
(86) PCT No.: PCT/JP2007/057899

§ 371 Date: Oct. 23, 2008

(30) Foreign Application Priority Data
Apr. 24, 2006 (JP) 2006-119773

(51) Int. Cl. H05H 1/24; C23C 16/00

(52) U.S. Cl. 427/569; 118/723 R

(57) ABSTRACT

An object to be processed (e.g., semiconductor wafer W) having a recess formed in a surface thereof is placed on a stage 34 disposed in a processing vessel 24 capable of being vacuumized. Thereafter, a plasma is generated in the processing vessel 24, so that a metal target 70 is ionized by the plasma to generate metal ions in the processing vessel 24. Then, a thin film is deposited on the surface of the object to be processed including a surface in the recess, by supplying a bias power to the stage 34 so as to draw the metal ions into the object to be processed placed on the stage 34 by the supplied bias power. In the present invention, a wattage of the bias power is varied within a range in which the surface of the object to be processed is not substantially sputtered.

### CROSS REFERENCE TO RELATED APPLICATIONS

This application is based upon the International Application No. PCT/JP2007/057899 filed on Apr. 10, 2007, the entire contents of which are incorporated herein by reference.

### FIELD OF THE INVENTION

The present invention relates to a film deposition method, a film deposition apparatus, and a storage medium. In particular, the present invention relates to a film deposition method, a film deposition apparatus, and a storage medium, for depositing a film such as a barrier film and a seed film, so as to fill a recess in an object to be processed such as a semiconductor wafer.

### BACKGROUND ART

When a semiconductor device is manufactured, a semiconductor wafer is generally repeatedly subjected to various processes such as a film deposition process and a pattern etching process, so as to manufacture a desired device. In view of recent demand for higher integration and further miniaturization of a semiconductor device, a line width and/or a hole diameter of the semiconductor device have been made smaller and smaller. In accordance with such smaller dimensions, an electric resistance has to be made smaller, whereby there is a tendency to use copper as a wiring material and/or an embedded material, because copper has a significantly small electric resistance and is inexpensive (see, JP2000-77365A, JP10-74760A, JP10-214836A, and JP2005-285820A). When copper is used as a wiring material and/or an embedded material, a tantalum metal (Ta) film or a tantalum nitride (TaN) film is used as a barrier layer, in consideration of adhesive properties between the copper material and a lower layer thereof.

In order to fill a recess formed in a semiconductor wafer, in a plasma sputtering apparatus, a thin seed film made of a copper film is firstly formed over all the surface of the wafer including the whole wall surface in the recess on which the barrier layer has been already formed, and then the entire wafer surface is plated with copper so as to completely fill the recess. Thereafter, the excessive copper thin film and the barrier layer on the surface of the wafer are polished and removed by a CMP (Chemical Mechanical Polishing) process or the like.

Filling of the recess formed in the semiconductor wafer is concretely described with reference to FIGS. 8 to 10. FIG. 8 is a sectional perspective view showing an example of the recess formed in the surface of the semiconductor wafer. FIG. 9 is a view showing a series of steps in a conventional film deposition method for filling a part of the recess shown in FIG. 8. FIG. 10 is a view for explaining a state in which an overhung portion is formed. FIG. 8 shows that a recess 2 of a laterally elongated groove (trench) having a rectangular shape in cross section, and a hole-like recess 4, such as a via hole and a through hole, formed in a bottom of the recess 2, are formed in an insulation layer 3 formed on a surface of a semiconductor wafer W. The recesses 2 and 4 define a two-stepped structure.

In the illustrated example, a wiring layer 6 as a lower layer is formed below the hole-like recess 4. By filling the recess 4 with a conductive member, the insulation layer 3 can have a conductivity on both sides thereof. The two-stepped structure is referred to as Dual Damascene structure. There is a case in which only the groove-like recess 2 or only the hole-like recess 4 is formed. In response to a demand for the miniaturization by the design rule, a groove width and a hole diameter of the recess 2 and the recess 4 are significantly made smaller. Thus, an aspect ratio (=depth/opening width (or opening diameter) showing a lengthwise-to-crosswise dimensional ratio of the recess 2 or 4 is enlarged to, e.g., about three to four times.

With reference to FIG. 9, a method of filling the hole-like recess 4 is mainly described. A barrier layer 8, which is of a stacked structure including a TaN film and a Ta film, for example, has been previously formed as a base layer in substantially a uniform manner on the surface of the semiconductor wafer W including an inner surface of the recess 4 by a plasma sputtering apparatus (see, FIG. 9(A)). Then, by the plasma sputtering apparatus, a seed film 10 of a thin copper film is formed as a metal film on the overall surface of the wafer W including the surface inside the recess 4 (see, FIG. 9 (B)). During the formation of the seed film 10 in the plasma sputtering apparatus, a bias power of a radiofrequency voltage is applied to the semiconductor wafer side so as to promote efficient drawing of metal ions of copper.

In general, a film thickness of the barrier layer 8 is about 10 nm, while a film thickness of the seed film 10 is about 50 to 80 nm. In addition, by plating the wafer surface with copper, the inside of the recess 4 is filled with a metal film 12 made of, e.g., a copper film. At this time, the upper groove-like recess 2 is also filled with the metal film 12. Thereafter, the excessive metal film 12, the seed film 10, and the barrier layer 8 on the wafer surface are polished and removed by the aforementioned CMP process or the like.

### SUMMARY OF THE INVENTION

When a film deposition process is performed in a plasma sputtering apparatus, it is general to apply a bias power to a semiconductor wafer side so as to promote drawing of metal ions, which has been as described above, so as to increase an amount of a deposited film. In this case, when a bias power is excessively raised, a surface of the wafer is undesirably sputtered by ions of an inert gas, such as an argon gas, which is a plasma exciting gas that has been introduced into the apparatus so as to generate a plasma. Namely, a metal film which has been purposely deposited is undesirably scraped. Thus, the bias power is not set at a significantly high value.

However, as shown in FIG. 9(B), when the seed film 10 made of a copper film is formed as described above, generated on a part of the seed film 10 on the upper opening of the recess 4 is an overhung portion 14 which projects to narrow the opening. Thus, when the inside of the recess 4 is intended to be filled with the metal film 12 made of a copper film in the succeeding plating process, there is a possibility that a plating liquid cannot sufficiently invade the inside of the recess 4. When the inside of the recess 4 is insufficiently filled, a void (gap) 16 may be formed therein.

A reason for the formation of the overhung portion 14 is described with reference to FIG. 10. As metal (Cu) particles scattering at the plasma sputtering, there are neutral particles in addition to metal ions ionized by a plasma. The metal ions are sucked by the bias power, so that the metal ions come from above in substantially a vertical direction with a directivity and deposit on the wafer surface. On the other hand, the neutral particles come onto the wafer surface from all the directions. In particular, neutral particles C1 diagonally flying to reach the wafer has a tendency to adhere to corner portions of the upper opening of the recess 4.

When the metal film, which has been deposited on the corner portions of the opening, is sputtered by metal particles and metal ions C2, other metal particles C3 are beaten out. The beaten-out metal particles C3 may again adhere to the opposed corner portions.

When the seed film 10 is formed, although the wafer is cooled so as to restrain a surface diffusion of the deposition film, occurrence of surface diffusion cannot be totally avoided. In this case, since metal particles on the surface of the deposition film are moved by the surface diffusion, the metal film deposited on the upper corner portions of the recess 4 would spherically gather to reduce a surface area thereof upon the surface diffusion. Thus, the metal film moves to produce a curved projection. For these reasons, the overhung portion 14 is formed.

In order to prevent the formation of the above overhung portion 14, it can be considered that a film thickness of the seed film 10 is reduced. However, this may invite the following problems. Namely, due to the high directivity of the metal ions, although the seed film 10 of a sufficient thickness can be formed on the bottom of the recess 4, there remain some parts of the sidewall in the recess 4 on which nearly no seed film is deposited. Alternatively, the film thickness of the seed film 10 becomes very non-uniform. These problems may arise, not only when the seed film 10 is formed, but also when the barrier layer 8 formed of a Ta film and a TaN film, for example, is formed with the use of the plasma sputtering apparatus.

These problems are particularly conspicuous, when the recesses 2 and 4 have a groove width and a hole diameter not more than 100 nm in order to cope with a further miniaturization thereof. Thus, an urgent solution of these problems is desired.

In view of the aforementioned problems, the present invention has been made so as to effectively solve the same. It is an object of the present invention to provide a film deposition method and a film deposition apparatus, which are capable of forming a thin film, such as a seed film and a barrier layer, having a sufficient thickness, on an inner wall surface of a recess without generating an overhung portion. It is another object of the present invention to provide a storage medium storing the film deposition method.

A film deposition method of the present invention is a film deposition method comprising the steps of: placing an object to be processed having a recess formed in a surface thereof, on a stage disposed inside a processing vessel capable of being vacuumized; generating a plasma inside the processing vessel; generating, inside the processing vessel, metal ions by ionizing a metal target by the plasma; depositing a thin film on the surface of the object to be processed including a surface in the recess, by supplying a bias power to the stage so as to draw the metal ions by the supplied bias power into the object to be processed placed on the stage; and varying a wattage of the bias power within a range in which the surface of the object to be processed is not substantially sputtered.

In the film deposition method according to the invention, it is preferable that a manner of varying a wattage of the bias power is stepwise in which a wattage of the bias power is varied in a plurality of steps with respect to an elapse of time. Alternatively, it is preferable that a manner of varying a wattage of the bias power is linear in which a wattage of the bias power is linearly varied with respect to an elapse of time. Alternatively, it is preferable that a manner of varying a wattage of the bias power is curvilinear in which a wattage of the bias power is curvilinearly varied with respect to an elapse of time.

In the film deposition method of the present invention, it is preferable that the recess of the object to be processed is a hole or a trench (groove), and a diameter or a width thereof is not more than 100 nm. Further, it is preferable that a wattage of the bias power is varied within a range not more than 0.29 W/cm². Furthermore, it is preferable that a pressure in the processing vessel is not less than 6.7 Pa.

In the film deposition method of the present invention, it is preferable that the thin film is a barrier layer or a seed film for plating.

A film deposition apparatus of the present invention is a film deposition apparatus comprising: a processing vessel capable of being vacuumized; a stage disposed inside the processing vessel, for placing thereon an object to be processed having a recess formed in a surface thereof; a plasma generating source disposed on the processing vessel, the plasma generating source being configured to generate a plasma in the processing vessel; a metal target disposed inside the processing vessel; the metal target being configured to be ionized by the plasma generated by the plasma generating source so as to generate metal ions; a bias power supply configured to supply a bias power to the stage; and a control part configured to control an operation of the bias power supply; wherein: a thin film is deposited on the surface of the object to be processed including a surface in the recess, by drawing the metal ions by the bias power into the object to be processed placed on the stage; and the control part controls the bias power supply such that a wattage of the bias power is varied within a range in which the surface of the object to be processed is not substantially sputtered.

A storage medium of the present invention A storage medium storing a program for causing a film deposition apparatus to deposit a thin film on a surface of an object to be processed having a recess formed in the surface thereof, wherein the program implements a film deposition method comprising the steps of: placing an object to be processed having a recess formed in a surface thereof, on a stage disposed inside a processing vessel capable of being vacuumized; generating a plasma inside the processing vessel; generating, inside the processing vessel, metal ions by ionizing a metal target by the plasma; depositing a thin film on the surface of the object to be processed including a surface in the recess, by supplying a bias power to the stage so as to draw the metal ions by the supplied bias power into the object to be processed placed on the stage; and varying a wattage of the bias power within a range in which the surface of the object to be processed is not substantially sputtered.

According to the film deposition method, the film deposition apparatus, and the storage medium of the present invention, the following excellent effect can be produced.

By varying a wattage of a bias power within a range in which a surface of an object to be processed is not substantially sputtered, no sputtering occur and thus generation of an overhung portion can be prevented on an opening of a recess formed in the surface of the object to be processed. In addition, a directivity of metal ions varies in the course of a film deposition, a thin film, such as a seed film and a barrier layer, can be relatively uniformly over substantially all the surface including not only a bottom of the recess but also a side wall in the recess.

### BRIEF DESCRIPTION OF THE DRAWINGS

FIG. 1 is a sectional view showing an example of a film deposition apparatus of the present invention.

FIG. 2 is a graph showing a relationship between a wattage of a bias power and a film deposition amount on an upper surface of a wafer.

FIG. 3 is a graph showing a relationship between a wattage of a bias power and a bottom coverage of a recess.

FIG. 4 is a graph showing a relationship between a wattage of a bias power and a sidewall coverage of a recess.

FIG. 5 is a view for explaining a principle of forming a thin film on an entire sidewall of a recess by the film deposition method of the present invention.

FIG. 6 is an example of a variation of wattage of a bias power in a film deposition method of the present invention.

FIG. 7 are SEM pictures showing a state in which the film deposition method of the present invention was applied to a formation of a barrier layer formed of a Ta film.

FIG. 8 is a perspective sectional view showing an example of a recess formed in a surface of a semiconductor wafer.

FIG. 9 is a view showing a series of steps of a conventional film deposition method for filling a part of the recess shown in FIG. 8.

FIG. 10 is a view for explaining a state in which an overhung portion is formed.

### DETAILED DESCRIPTION OF THE INVENTION

Embodiments of a film deposition method, a film deposition apparatus, and a storage medium of the present invention will be described herebelow with reference to the accompanying drawings.

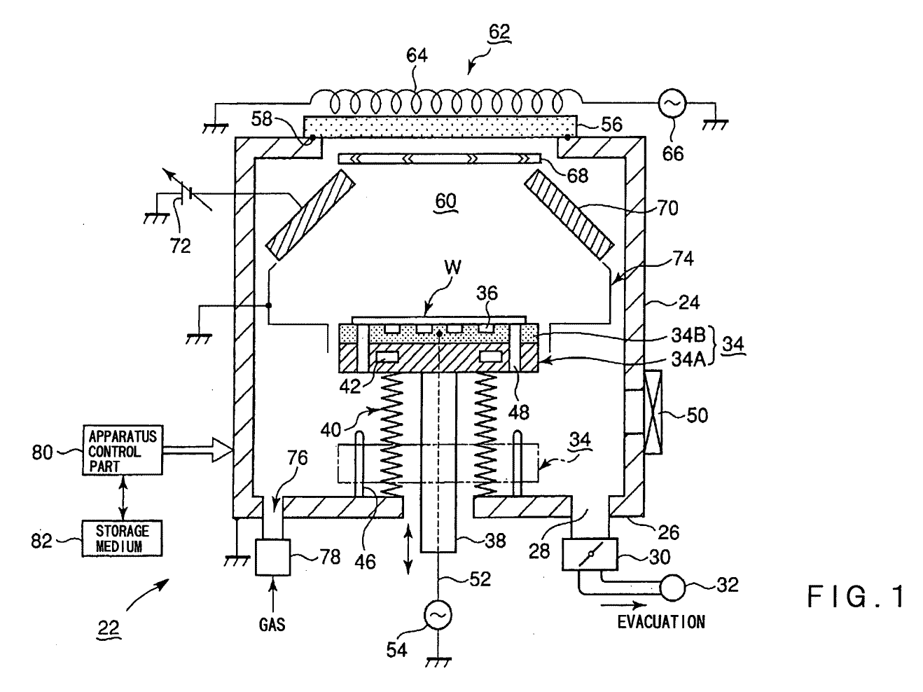

FIG. 1 is a sectional view showing an example of a film deposition apparatus of the present invention. Given herein as an example to describe the present invention is a case where an ICP (Inductively Coupled Plasma) type sputtering apparatus is used as the film deposition apparatus. As shown in FIG. 1, the plasma film deposition apparatus 22 includes a cylindrical processing vessel 24 made of, e.g., aluminum. The processing vessel 24 is grounded. A bottom 26 of the processing vessel 24 is provided with an exhaust port 28. The processing vessel 24 can be vacuumized by a vacuum pump 32 through a throttle valve 30 that adjusts a pressure.

Disposed in the processing vessel 24 is a discoid stage 34 made of, e.g., aluminum. The stage 34 is composed of a stage body 34A and an electrostatic chuck 34B placed on an upper surface of the stage body 34A. The electrostatic chuck 34B is capable of absorbing and holding a semiconductor wafer W as an object to be processed. Formed in an upper surface side of the electrostatic chuck 34B is a gas groove 36 through which a heat conductive gas flows. According to need, a heat conductive gas such as an Ar gas (argon gas) is supplied to the gas groove 36 so as to improve a heat conductivity between the wafer W and the stage 34. As circumstances demand, a DC voltage for absorption is applied to the electrostatic chuck 34B by a DC power supply, not shown. The stage 34 is supported by a column 38 extending downward from a center part of a lower surface of the stage 34. A lower part of the column 38 passes through the bottom 26 of the processing vessel 24. The column 38 is capable of moving in an up and down direction by an elevating mechanism, not shown, so that the stage 34 itself can be elevated and lowered.

A metal bellows 40 capable of being expanded and contracted is disposed to surround the column 38. An upper end of the metal bellows 40 is air-tightly joined to the lower surface of the stage 34, and a lower end thereof is air-tightly joined to an upper surface of the bottom 26 of the processing vessel 24. The metal bellows 40 allows an up and down movement of the stage 34, while maintaining an air-tightness in the processing vessel 24. Formed in the stage body 34A of the stage 34 is a coolant circulation path 42 as a cooling means, through which a coolant for cooling a wafer W flows. The coolant is supplied and discharged through a flow path, not shown, in the column 38.

A plurality of, e.g., three support pins 46 (only two support pins 46 are illustrated) are disposed to project upward from the bottom 26 of the processing vessel 24. The stage 34 is provided with pin through-holes 48 corresponding to the support pins 46. Thus, when the stage 34 is lowered, a wafer W can be received by upper ends of the support pins 46 passing through the pin through-holes 48, and the wafer W can be transferred between the support pins 46 and a transfer arm, not shown, which comes into the processing vessel 24 from outside. To this end, a gate valve 50, which is capable of being opened and closed for allowing an entrance of the transfer arm, is disposed in a lower sidewall of the processing vessel 24.

Connected through a wiring 52 to the electrostatic chuck 34B placed on the stage body 34A is a bias power supply 54 formed of a radiofrequency power supply for generating a radiofrequency of, e.g., 13.56 MHz. The bias power supply 54 is capable of applying a predetermined bias power to the stage 34. In addition, the bias power supply 54 is capable of variably controlling a wattage of a bias power to be outputted, according to need.

On the other hand, a transmission plate 56 made of a dielectric material such as aluminum oxide, which can transmit a radiofrequency, is air-tightly disposed on a ceiling part of the processing vessel 24, through a sealing member 58 such as an O-ring. Disposed on the transmission plate 56 is a plasma generating source 62 that makes, e.g., an argon gas, which is a plasma exciting gas, into plasma in a processing space 60 in the processing vessel 24. In place of Ar, another inert gas such as He and Ne may be used as the plasma exciting gas. Specifically, the above plasma generating source 62 has an inductive coil part 64 disposed to correspond to the transmission plate 56. Connected to the inductive coil part 64 is a radiofrequency power supply 66 for generating a radiofrequency of 13.56 MHz for generating a plasma, so that a radiofrequency can be introduced to the processing space 60 through the transmission plate 56. A wattage of the power for generating a plasma which is outputted from the radiofrequency power supply 66 can be also controlled according to need.

Disposed immediately below the transmission plate 56 is a baffle plate 68 made of, e.g., aluminum, for diffusing a radiofrequency that has been introduced. Disposed below the baffle plate 68 is a metal target 70 that surrounds an upper lateral side of the processing space 60. The metal target 70 has an annular (truncated conical) shape, with its section being inclined inward, for example. Connected to the metal target 70 is a DC power supply 72 for target, which supplies a power for discharge whose wattage can be varied. In place of the DC power supply, an AC power supply may be used. A wattage of the DC power that is outputted from the DC power supply 72 can also be controlled according to need. As the metal target 70, tantalum metal and copper are used, for example. These metals are sputtered as metal atoms or metal atom groups by Ar ions (argon ions) in a plasma, and a larger part thereof is ionized when passing through the plasma. The tantalum metal is used when a barrier layer (described below) is formed, and the copper is used when a seed film (described below) is formed.

Below the metal target 70, there is provided a cylindrical protective cover 74 made of, e.g., aluminum so as to surround the processing space 60. The protective cover 74 is grounded, and a lower part thereof is bent inward so as to be positioned adjacent to a side part of the stage 34. The bottom 26 of the processing vessel 24 is provided with a gas inlet port 76 as a gas introduction means for introducing a required predetermined gas into the processing vessel 24. A plasma exciting gas such as an Ar gas, and another required gas such as an N₂ gas, are supplied from the gas inlet port 76 through a gas control part 78 formed of a gas flow rate adjuster and a valve.

The respective constituent elements of the plasma film deposition apparatus 22 are connected to an apparatus control part 80 formed of a computer, and are configured to be controlled by the apparatus control part 80. To be specific, the apparatus control part 80 is configured to control operations of the bias power supply 54, the radiofrequency power supply 66 for generating a plasma, the DC power supply 72, the gas control part 78, the throttle valve 30, and the vacuum pump 32. When a thin film is formed by the method of the present invention, the apparatus control part 80 works as follows.

At first, under the control of the apparatus control part 80, the inside of the processing vessel 24 is vacuumized by operating the vacuum pump 32. Then, by operating the gas control part 78, an Ar gas is caused to flow into the vacuumized processing vessel 24. Then, by controlling the throttle valve 30, the inside of the processing vessel 24 is maintained at a predetermined vacuum degree. Thereafter, a DC power is applied to the metal target 70 by the DC power supply 72, and a radiofrequency power (plasma power) is applied to the inductive coil part 64 by the radiofrequency power supply 66.

On the other hand, the apparatus control part 80 gives a command to the bias power supply 54 so that a bias power of a predetermined wattage is applied to the stage 34. In the processing vessel 24 thus controlled, an argon plasma is formed by the plasma power applied to the inductive coil part 64, and Ar ions are generated. These ions collide with the metal target 70 to which the DC power is supplied from the DC power supply 72, whereby the metal target 70 is sputtered to release metal particles.

Many of metal atoms and metal atom groups which are the metal particles released from the sputtered metal target 70 are ionized when passing through the plasma. The metal particles, in which the ionized metal ions and the neutral metal atoms, which are electrically neutral, are mixed each other, scatter downward. In particular, a pressure in the processing vessel 24 is set at a relatively high value, specifically at 6.7 Pa (50 mTorr) or more for example. Thus, a plasma density in the processing vessel 24 is elevated, so that the metal particles can be ionized at a high efficiency.

When the metal ions enter an area of an ion sheath having a thickness of several millimeters, the area having been generated on the surface of the wafer by the bias power applied to the stage 34, the metal ions are drawn toward the wafer W at an accelerated rate with a high directivity so as to be deposited on the wafer W. The thin film formed by depositing the metal ions with a high directivity can basically have a vertical coverage.

As will be described below, when a seed film for plating and a barrier layer are formed, the apparatus control part 80 controls an upper limit of a wattage of an output of the bias power supply 54, for example. Concretely, a film deposition is performed such that a wattage of the bias power is varied within a range in which a wafer surface is not substantially sputtered. The respective constituent elements of the apparatus are controlled by the apparatus control part 80, based on a program which is created so as to realize a deposition of a metal film under a predetermined condition. The program including commands for controlling the respective constituent elements has been stored in a storage medium 82, such as a floppy disk (registered trademark) (FD), a compact disk (registered trademark) (CD), a flash memory, and a hard disk. Based on the program, the apparatus control part 80 controls the respective constituent elements so as to perform a process under the predetermined condition.

Next, there is described a film deposition method of the present invention performed by the plasma film deposition apparatus 22 as structured above.

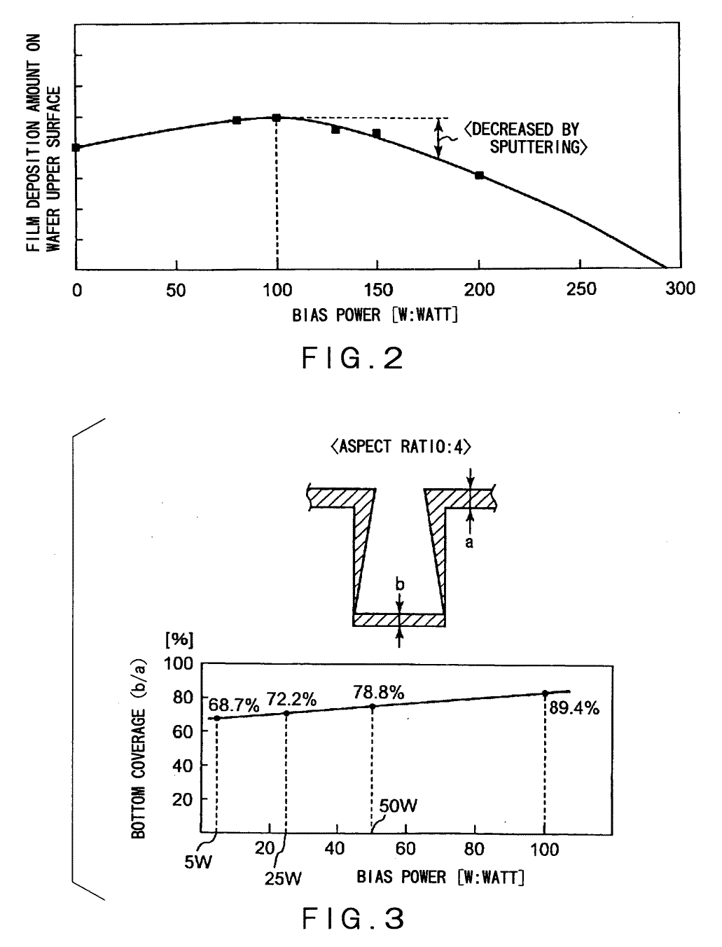

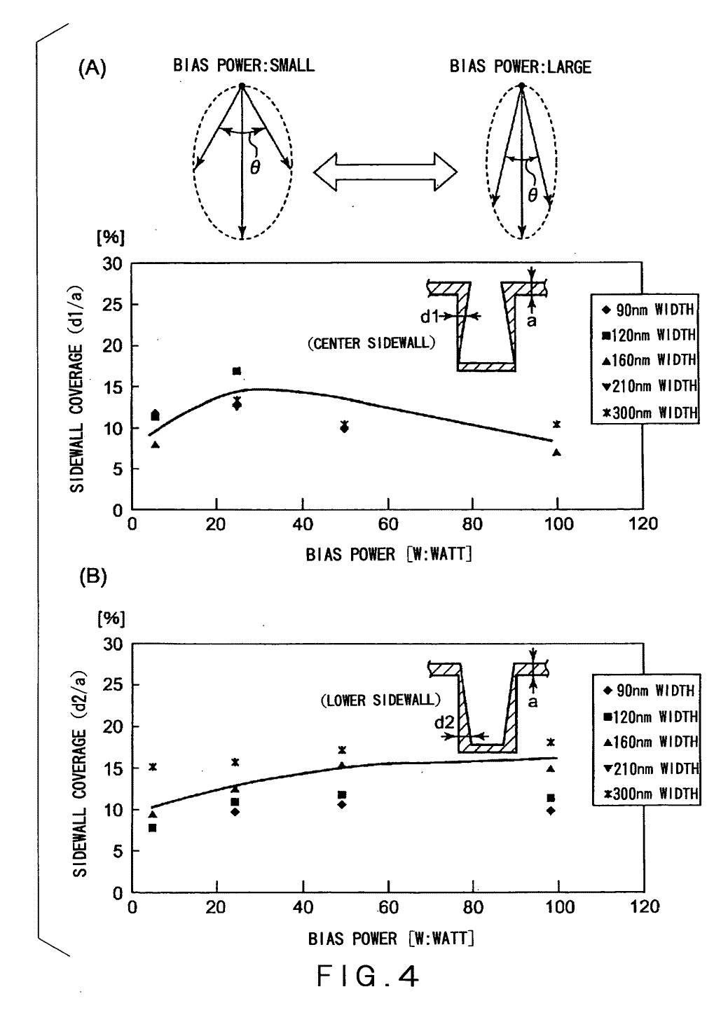

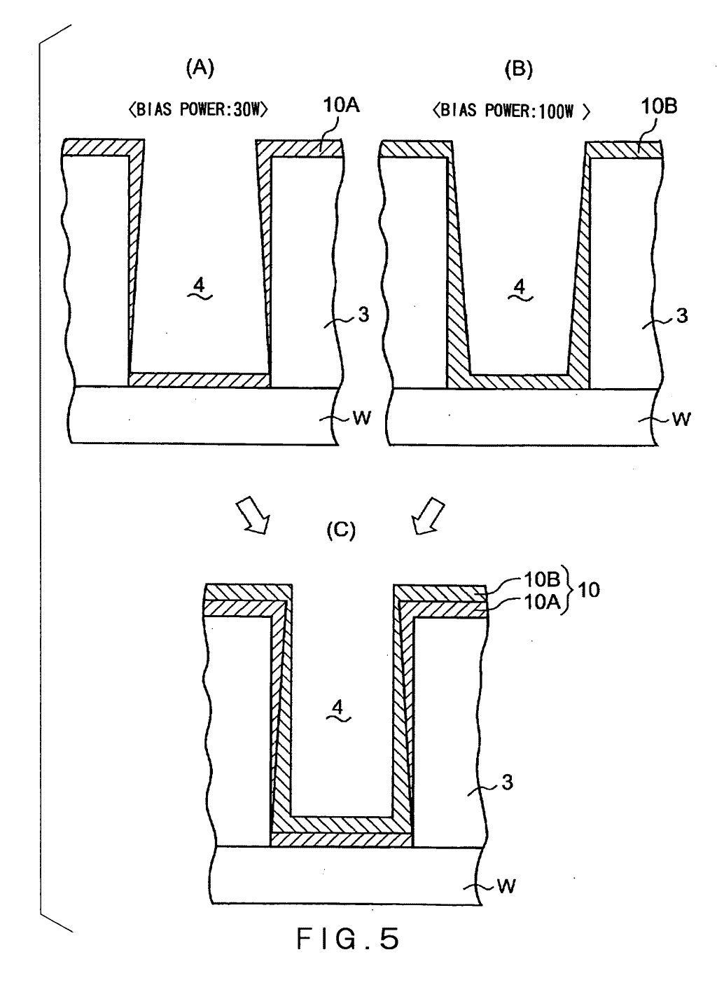

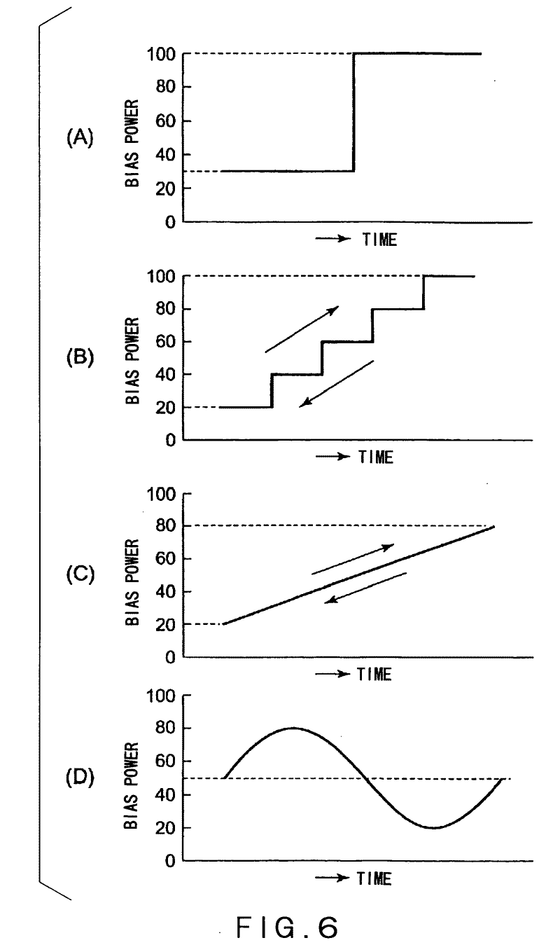

FIG. 2 is a graph showing a relationship between a wattage of a bias power and a film deposition amount on an upper surface of a wafer. FIG. 3 is a graph showing a relationship between a wattage of a bias power and a bottom coverage of a recess. FIG. 4 is a graph showing a relationship between a wattage of a bias power and a sidewall coverage of a recess. FIG. 5 is a view for explaining a principle of forming a thin film on an entire sidewall of a recess by the film deposition method of the present invention. FIG. 6 is an example of a variation of wattage of a bias power in the film deposition method of the present invention.

The feature of the film deposition method of the present invention resides in varying a wattage of a bias power applied to the stage 34 by the bias power supply 54 within a range in which a surface of a semiconductor wafer W is not sputtered. When a wattage of a bias power is increased and exceeds a certain value, collision of Ar ions to the wafer surface becomes excessively strong, and a thin film that has been deposited starts to be sputtered (resputtered) by the collision of the Ar ions. The higher the wattage of the bias power is, the sputtering becomes more intensive. This sputtering by the Ar ions causes generation of the overhung portion 14 which has been described with reference to FIG. 10. Thus, in the film deposition method of the present invention, in order to prevent the generation of the overhung portion 14, a wattage of the bias power is set within a range in which the sputtering of the Ar ions does not start. In addition, in the film deposition method of the present invention, in order that a thin film is deposited on an entire area of a sidewall of a recess, a wattage of the bias power during the film deposition is controlled to be properly varied such that a directivity of the metal ions, i.e., an angular distribution of the metal ions is varied. These points are described in more detail below.

That is to say, in the film deposition apparatus formed of the ICP type sputtering apparatus as shown in FIG. 1, a relationship between a wattage of a bias power applied to a wafer W side, and an amount of a film deposited on the wafer upper surface (not a sidewall of a recess) is as shown in FIG. 2. Herein, a wattage (wattage of the bias power) in the axis of abscissa varies depending on a kind of a target and wafer size. The numerical values in FIG. 2 are obtained when the target is copper and the wafer size is 200 mm, for example. That is to say, under a state in which a plasma power of a certain wattage is applied to the inductive coil part 64 and a DC power of a certain wattage is applied to the metal target 70, when the bias power is not so high, an excellent film deposition amount is obtained by the drawing of metal ions and by the neutral metal atoms. Further, the film deposition amount is gradually increased in accordance with the increase of the bias power.

When the bias power is increased to exceeds a given value, e.g., about 100 W (a value of the bias power per unit area: 0.32 W/cm²), the wafer surface starts to be sputtered by the Ar ions as a plasma gas that is accelerated by the bias power. This sputtering is gradually precipitated, and thus the metal film that has been deposited is undesirably etched. As a matter of course, the larger the bias power becomes, the etching becomes more serious.

Thereafter, the bias power is further increased, the amount of the film deposited by the drawn metal ions and the neutral metal atoms becomes equal to the etching amount of the film that is sputtered and etched by the ions of the plasma gas. In this case, the film deposition process and the etching process balance out, so that the film deposition amount on the wafer upper surface is decreased to “zero”. The bias power and the film deposition amount in FIG. 2 are merely taken by way of example. By controlling a wattage of the bias power and a wattage of the DC power, the above characteristic curve varies with its shape being maintained in an analogue manner.

<Examination of Bottom Coverage in Recess>

There is examined a deposition state of a thin film deposited on a bottom in a recess (bottom coverage), when a wattage of the bias power is within a range in which the wafer surface is not substantially sputtered, i.e., not more than 100 W in FIG. 2. A result of the bottom coverage is shown in FIG. 3. An aspect ratio (=depth/opening width (or opening diameter)) of the recess is “4”. As schematically shown in FIG. 3, a definition of the bottom coverage is represented as “a film thickness b of the film on the bottom of the recess/a film thickness a of the film on the wafer upper surface”, i.e., “b/a”. As shown in FIG. 3, when a wattage of the bias power is varied from 5 W to 100 W, the bottom coverage is increased substantially linearly from 68.7% to 89.4%. Thus, it was confirmed that, when a wattage of the bias power is not more than 100 W, a thin film having a sufficient thickness can be deposited on the bottom in the recess.

<Examination of Sidewall Coverage in Recess>

Next, there is examined a deposition state of a thin film deposited on a sidewall in a recess (sidewall coverage), when a wattage of the bias power is within a range in which the wafer surface is not substantially sputtered (not more than 100 W) in FIG. 2. A result of the sidewall coverage is shown in FIG. 4. An aspect ratio of the recess is “4”. The width of the recess varies in a range between 90 nm and 300 nm. As schematically shown in FIG. 4, a definition of the sidewall coverage is represented as “a film thickness d of the film on the sidewall in the recess/a film thickness a of the film on the wafer upper surface”, i.e., “d/a”. FIG. 4(A) shows a sidewall coverage (d1/a) at a center position in the recess in a height direction, and FIG. 4(B) shows a sidewall coverage (d2/a) at a lower position in the recess. As shown in FIG. 4(A), when the bias power is small, an angular distribution θ of metal ions is wide so that a directivity is small. On the other hand, as the bias power is increased, an angular distribution θ of the metal ions is narrowed so that a directivity is increased.

As shown in FIG. 4, the film deposition state with respect to the variation of the bias power differs depending on the positions of the sidewall of the recess in the height direction. Namely, as shown in FIG. 4(A), in the sidewall at the center position in the recess in the height direction, there is a peak of the sidewall coverage when the bias power is about 30 W. The sidewall coverage is gradually reduced in symmetry in the right and left direction about the peak in the graph of FIG. 4(A). This is because, when the bias power becomes larger than about 30 W, the angular distribution θ of the metal ions becomes smaller, whereby the contribution of the metal ions to the sidewall at the center position in the recess in the height direction is reduced.

On the other hand, as shown in FIG. 4(B), in the sidewall at the lower position in the recess in the height direction, the sidewall coverage is gradually increased, as the bias power is increased. There is a peak when the bias power is 100 W. This is because, as the bias power is increased, the angular distribution θ of the metal ions becomes gradually smaller, whereby a collection efficiency of the metal ions onto the lower sidewall is enhanced.

Therefore, in accordance with the angular distribution θ of the metal ions, the thin film can be intensively deposited at the different positions of the sidewall of the recess in the height direction. It is thus understood that the thin film can be deposited over the entire area of the sidewall of the recess, by controlling to properly vary a wattage of the bias power during the film deposition. In other words, the angular distribution θ of the metal ions can be controlled by varying a wattage of the bias power, and thus the sidewall coverage in the recess can be controlled.

On the basis of the understanding of the above phenomena, the film deposition method of the present invention is described with reference also to FIGS. 5 and 6.

At first, in FIG. 1, the stage 34 is lowered. Then, a wafer W is loaded into the processing vessel 24 capable of being vacuumized through the gate valve 50 of the processing vessel 24, and the wafer W is placed on the support pins 46. Under this state, when the stage 34 is elevated, the wafer W is received by the upper surface of the stage 34. The wafer W is absorbed on the upper surface of the stage 34 by the electrostatic chuck 34B.

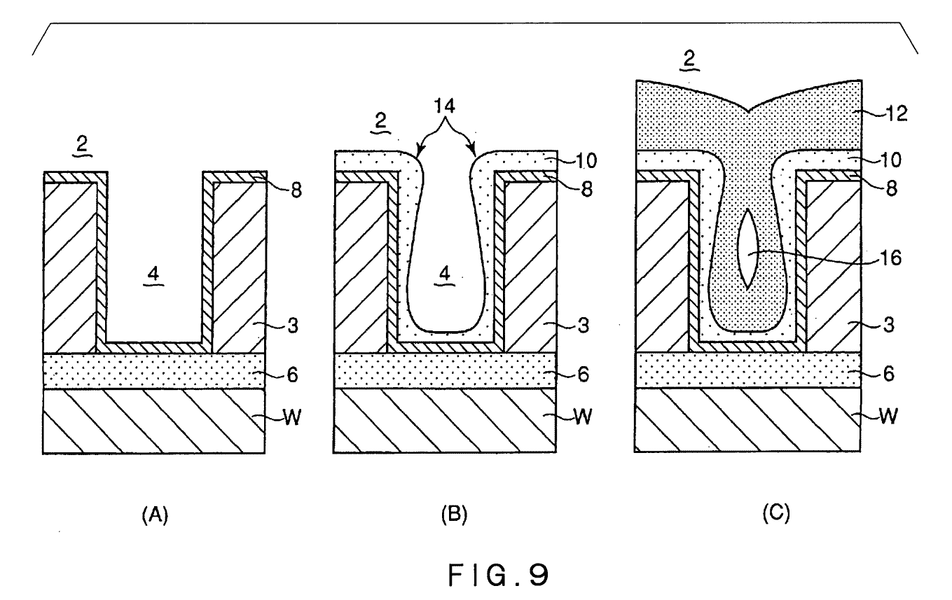

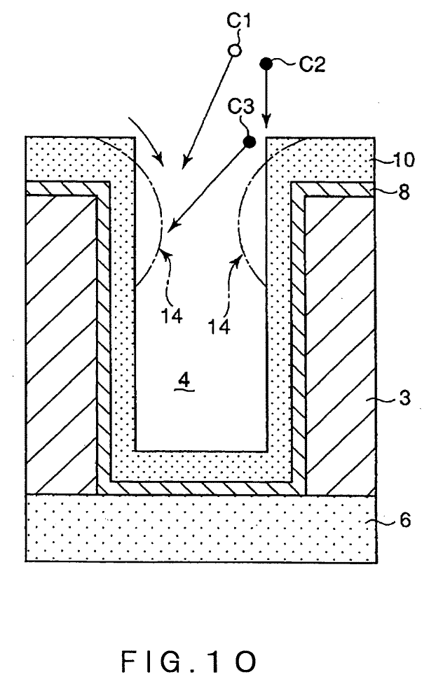

After the wafer W placed on the stage 34 and is absorbed and fixed thereto, the film deposition process is started. At this time, recesses 2 and 4, which are of the same structures as those described in FIGS. 8 and 9, have been formed beforehand in a previous step before the loading step. The upper recess 2 is formed of a groove-like trench. The lower recess 4 formed of a hole, such as a via hole and a through hole, is formed in a bottom of the recess 2 so as to reach the wiring layer 6. The upper recess 2 and the lower recess 4 define a two-stepped configuration as a whole. FIG. 5 typically shows only the lower recess 4. A barrier layer has been already formed on the surface of the wafer W in the previous step (illustration is omitted in FIG. 5).

As has been described above, in this embodiment, copper is used as the metal target 70 in order that the seed film 10 formed of a Cu film is formed. After the inside of the processing vessel 24 has been vacuumized to a predetermined pressure, a plasma power of a predetermined wattage is applied to the inductive coil part 64 of the plasma generating source 62, and a bias power is applied from the bias power supply 54 to the electrostatic chuck 34B of the stage 34. In addition, a DC power of a predetermined wattage is applied from the DC power supply 72 to the metal target 70, so as to deposit a film. In this case, in order to form a Cu film, an Ar gas, for example, as a plasma exciting gas is supplied into the processing vessel 24 through the gas inlet port 76.

When the seed film 10 is formed by the film deposition method of the present invention, a wattage of the bias power is varied in a plurality of steps, i.e., two steps in this embodiment as shown in FIG. 6(A). In an initial step (first step), a wattage of the bias power is set at 30 W, and the film deposition process is performed for a predetermined period of time. In a succeeding step (second step), a wattage of the bias power is varied to 100 W, and the film deposition process is performed for a predetermined period of time.

FIG. 5 schematically shows states of the film deposited on the inner wall surface of the recess 4 in the first step and the second step. FIG. 5(A) is a schematic view showing the film deposition state in the first step, and FIG. 5(B) is a schematic view showing the film deposition state in the second step. Namely, in the case of FIG. 5(A), a film deposition amount of a seed film 10A at the lower position of the sidewall in the recess 4 is considerably smaller as that of other sidewall portions, which has been described above with reference to FIG. 4(A).

On the other hand, in the case of FIG. 5(B), a film deposition amount of a seed film 10B at the lower position of the sidewall in the recess is considerably larger, which has been described above with reference to FIG. 4(B).

Thus, by combining the seed film 10A shown in FIG. 5(A) and the seed film 10B show in FIG. 5(B), it is possible to form the seed film 10 as a thin film over substantially the all surface of the sidewall including the bottom in the recess 4 in a relatively uniform manner, as shown in FIG. 5(C). The order of the first step shown in FIG. 5(A) and the second step show in FIG. 5(B) may be reversed.

An example of the process condition in this case is as follows. A process pressure is 10 Pa (75 mTorr), an ICP power is 5.25 kW, a DC power is 7.0 kW, and a film thickness of the seed film is 55 nm.

In this manner, it is possible to intensively deposit the thin film on the different positions of the sidewall of the recess in the height direction. As a result, it is understood that a thin film can be deposited over all the area of the sidewall of the recess, by controlling to properly vary a wattage of the bias power during the film deposition process.

A wattage of the bias power is varied within a range in which the wafer surface is not substantially sputtered. Thus, there is no possibility that an overhung portion is generated on the opening of the recess 4. As described above, in order to absolutely prevent the formation of an overhung portion caused by the beaten-out metal particles which again adhere to the opposed corners, which is one of the causes of the generation of an overhung portion, it is preferable that a value of the bias power is less than 100 W, e.g., not more than 90 W which is about 90% of 100 W (not more than 0.29 W/cm² as a value of the bias power per unit area). This is because, although the film deposition amount on the wafer surface has a peak at 100 W as shown in FIG. 2, minute sputtering is considered to have already occurred.

In FIG. 6(A), the wattage of the bias power is varied in two steps, which is merely by way of example. It goes without saying the stepwise variation is not limited thereto.

To be specific, as show in FIG. 6(B), a wattage of the bias power may be varied in a number of steps, such as five steps, for example, or in three or four steps, or in six steps or more. Further, the stepwise variation of a wattage of the bias power may be varied in a reciprocating manner.

Further, as shown in FIG. 6(C), a wattage of the bias power may be varied to linearly increase or decrease with respect to an elapse of time. Furthermore, a wattage of the bias power may be varied curvilinearly with respect to an elapse of time. For example, as shown in FIG. 6(D), a wattage of the bias power may be varied to define a since curve. In addition, the bias power of “zero” watt may be included in the film deposition process. In any case, as long as the sputtering of the wafer surface does not occur, a wattage of the bias power may be varied linearly, or curvilinearly, and both linearly and curvilinearly, with respect to an elapse of time. After the seed film has been formed, a process for filling the recess by Cu is performed by plating, which has been as described above.

<Formation of Barrier Layer>

Given in the above embodiment as an example to describe the process is a case where the seed film formed of a Cu film is formed as a thin film. However, not limited thereto, the film deposition method of the present invention may be applied to a case in which a barrier layer formed of a Ta film and a TaN film is formed by a plasma sputtering apparatus. In this case, Ta is used as the metal target 70. When a TaN film is formed, an N₂ gas is introduced in addition thereto.

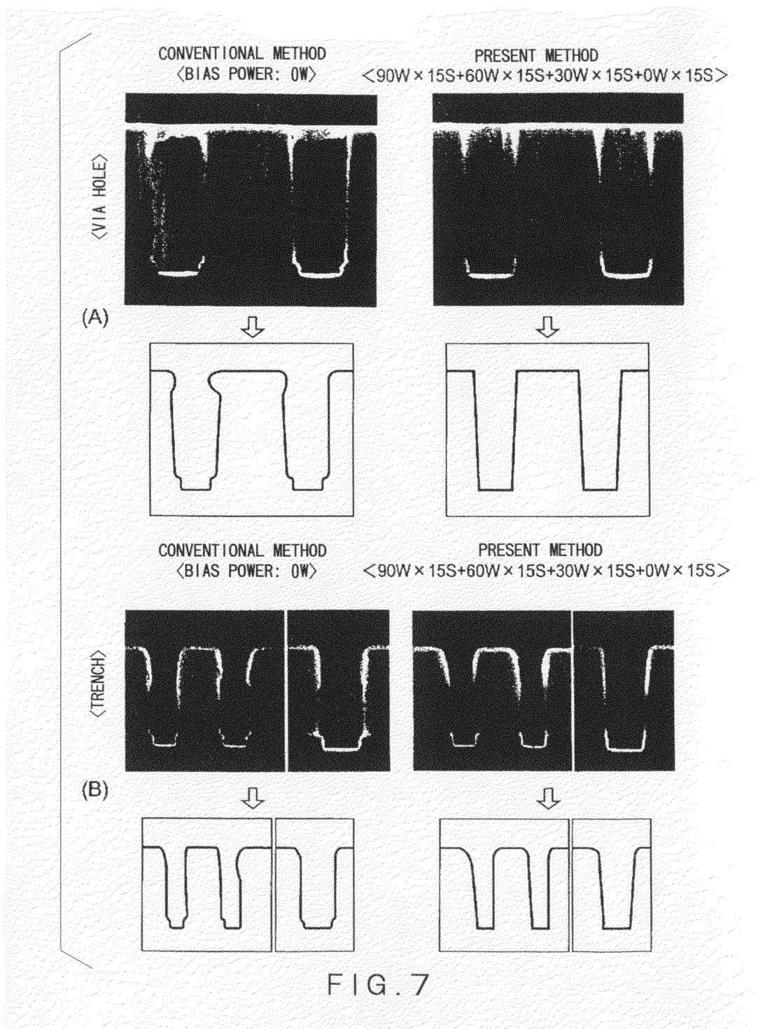

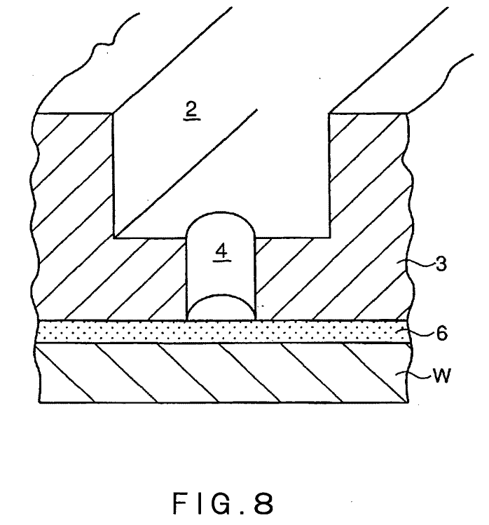

An evaluation test was conducted for a case in which the present method is applied to a formation of a barrier layer formed of a Ta film. An evaluation result is described below. FIG. 7 are SEM pictures showing a state in which the film deposition method of the present invention was applied to a formation of a barrier layer formed of a Ta film. FIG. 7 shows a case in which the bias power is “0 watt” for comparison, and schematic views are added for facilitating understanding.

FIG. 7(A) shows a via hole having a diameter of 100 nm, and FIG. 7(B) shows a trench having a groove width of 180 nm. A variation manner of a wattage of the bias power in the present method was “90 W×15 sec+60 W×15 sec+30 W×15 sec+0 W×15 sec”. A process condition was 8.7 Pa (65 mTorr) of a process pressure, 5.25 kW of an ICP power, 2.0 kW of a DC power, and 10 nm of a target film thickness.

Regarding an evaluation of a presence of the Ta film, since a film thickness thereof is too small to judge the presence of the film deposition, the wafer was immersed into 1% HF solution after the formation of the Ta film. Since an SiO₂ insulation film that is exposed to a part on which the Ta film was not formed is dissolved in the HF solution, the presence of the film deposition of the Ta film was evaluated by detecting the dissolved SiO₂ insulation film.

As shown in FIGS. 7(A) and 7(B), in a conventional case in which the bias power was 0 W, both in the via hole and the trench, the sidewalls are unnaturally enlarged and the SiO₂ insulation film is solved out. Thus, it can be understood that the Ta film is not sufficiently formed on these parts.

On the other hand, in a film deposition method of the present invention in which the bias power was varied stepwise, the shapes of the via hole and the trench are maintained properly. Thus, it can be confirmed that the Ta film is formed over substantially all the surface of the inner wall surface of the recess.

Given herein as an example to describe the case in which the Cu film and the Ta film are formed as thin films. However, not limited thereto, the film deposition method of the present invention may be naturally applied to all the cases in which a thin film is formed by using a plasma sputtering apparatus. For example, the film deposition method of the present invention may be applied when a metal such as tungsten (W), tantalum (Ta), and ruthenium (Ru), or an alloy of these metals is deposited to form a thin film.

In addition, not limited to 13.56 MHz, a frequency of each radiofrequency power supply may be another value such as 27.0 MHz. Moreover, not limited to an Ar gas, another inert gas such as He and Ne may be used as an inert gas for plasma.

Further, although a semiconductor wafer is taken as an example of an object to be processed, the present invention is not limited thereto, and may be applied to an LCD substrate, a glass substrate, a ceramic substrate, and so on.

1. A film deposition method comprising the steps of:
placing an object to be processed having a recess formed in a surface thereof, on a stage disposed inside a processing vessel capable of being vacuumized;
generating a plasma inside the processing vessel;
generating, inside the processing vessel, metal ions by ionizing a metal target by the plasma;
depositing a thin film on the surface of the object to be processed including a surface in the recess, by supplying a bias power to the stage so as to draw the metal ions by the supplied bias power into the object to be processed placed on the stage; and
varying a wattage of the bias power within a range in which the surface of the object to be processed is not substantially sputtered.

2. The film deposition method according to claim 1, wherein
a manner of varying a wattage of the bias power is stepwise in which a wattage of the bias power is varied in a plurality of steps with respect to an elapse of time.

3. The film deposition method according to claim 1, wherein
a manner of varying a wattage of the bias power is linear in which a wattage of the bias power is linearly varied with respect to an elapse of time.

4. The film deposition method according to claim 1, wherein
a manner of varying a wattage of the bias power is curvilinear in which a wattage of the bias power is curvilinearly varied with respect to an elapse of time.

5. The film deposition method according to claim 1, wherein
the recess of the object to be processed is a hole or a trench (groove), and a diameter or a width thereof is not more than 100 nm.

6. The film deposition method according to claim 1, wherein
a wattage of the bias power is varied within a range not more than 0.29 W/cm².

7. The film deposition method according to claim 1, wherein
a pressure in the processing vessel is not less than 6.7 Pa.

8. The film deposition method according to claim 1, wherein
the thin film is a barrier layer or a seed film for plating.

9. A film deposition apparatus comprising:
a processing vessel capable of being vacuumized;
a stage disposed inside the processing vessel, for placing thereon an object to be processed having a recess formed in a surface thereof;
a plasma generating source disposed on the processing vessel, the plasma generating source being configured to generate a plasma in the processing vessel;
a metal target disposed inside the processing vessel; the metal target being configured to be ionized by the plasma generated by the plasma generating source so as to generate metal ions;
a bias power supply configured to supply a bias power to the stage; and
a control part configured to control an operation of the bias power supply;
wherein:
a thin film is deposited on the surface of the object to be processed including a surface in the recess, by drawing the metal ions by the bias power into the object to be processed placed on the stage; and
the control part controls the bias power supply such that a wattage of the bias power is varied within a range in which the surface of the object to be processed is not substantially sputtered.

10. A storage medium storing a program for causing a film deposition apparatus to deposit a thin film on a surface of an object to be processed having a recess formed in the surface thereof,
wherein the program implements a film deposition method comprising the steps of:
placing an object to be processed having a recess formed in a surface thereof, on a stage disposed inside a processing vessel capable of being vacuumized;
generating a plasma inside the processing vessel;
generating, inside the processing vessel, metal ions by ionizing a metal target by the plasma;
depositing a thin film on the surface of the object to be processed including a surface in the recess, by supplying a bias power to the stage so as to draw the metal ions by the supplied bias power into the object to be processed placed on the stage; and
varying a wattage of the bias power within a range in which the surface of the object to be processed is not substantially sputtered.
